(19) United States
(12) Patent Application Publication
(10) Pub. No.: US 2008/0163817 A1
(43) Pub. Date: Jul. 10, 2008

(54) APPARATUS FOR GAS HANDLING IN VACUUM PROCESSES

(75) Inventor: Oliver Rattunde, Werdenberg (DE)

Correspondence Address: PEARNE & GORDON LLP, 1801 EAST 9TH STREET, SUITE 1200, CLEVELAND, OH, 44114-3108, US

(73) Assignee: OC OERLIKON BALZERS AG, Balzers (LI)

(21) Appl. No.: 11/968,717

(22) Filed: Jan. 3, 2008

Related U.S. Application Data
(60) Provisional application No. 60/883,348, filed on Jan. 4, 2007.

(51) Int. Cl. C23C 16/00

(52) U.S. Cl. 118/715

(57) ABSTRACT

In an apparatus for controlling a gas-rise pattern in a vacuum treatment process a gas inlet (1) is operatively connected with a mass-flow-controller MFC (2); said MFC (2) being again operatively connected via a first valve (5) with a vacuum chamber (3) and in parallel via second valve (6) with a vent-line (4). Said connection with the vent-line (4) further comprises means for varying the pump cross section of said vent-line (4). In another embodiment the apparatus for controlling a gas-rise pattern in a vacuum treatment process comprises a gas inlet (13) operatively connected with a vacuum chamber (3) via a valve (11), wherein the connection between gas inlet (13) and valve (11) further comprises a diaphragm (12).

This application claims the benefit of U.S. Provisional Patent Application No. 60/883,348 filed on Jan. 4, 2007. Said application is incorporated herein by reference.

### FIELD OF THE INVENTION

This invention relates to gas handling techniques, and more specifically to fast gas handling (increase/decrease of gas pressure) in a vacuum chamber. It is useful for vacuum sputtering apparatus especially for high pressure applications at high throughput at short cycle times.

### BACKGROUND OF THE INVENTION

Sputtering is a physical vapor deposition (PVD) process in vacuum whereby atoms in a solid target material are ejected into the gas phase due to bombardment of the material by energetic ions. The energetic ions are in the state of the art produced by ionization from inert gas, mostly argon. Sputtering is commonly used for thin-film deposition, as well as analytical techniques. Many processes in PVD (or chemical vapor deposition (CVD)) processing of substrates in a vacuum chamber require precise and fast variation of gas pressure. One typical application is high pressure sputtering in a multi chamber vacuum system where substrates are treated at high gas pressure while transport from one chamber to the other should be performed at significantly lower pressure in order not to disturb the neighboring chambers. Many of these applications (e.g. processing of disk-like substrates for the optical or magnetic datastorage industry) require short process times in order to guarantee high throughput.

One specific application is processing of magnetic disks for PMR (perpendicular magnetic recording), a technology used to increase storage density compared to commonly known LMR (longitudinal magnetic recording). The storage layer of current PMR media consists of a granular material like CoCrPt—SiO₂ deposited on a Ru layer, both sputtered at very high pressures (up to 1×10⁻¹ hPa) in order to optimize magnetic properties. Best performance concerning SNR (signal to noise ratio) has been achieved by sputtering the Ru layer in two steps (“2-step Ru”): A first layer is sputtered at low to medium pressure (10⁻³ hPa regime); a second layer is sputtered at very high pressure (10⁻² to 10⁻¹ hPa regime). The second layer at high pressure produces the desired grain size distribution for the above storage layer of about 6 nm whereas it has been speculated that the 1st layer is necessary to initiate the desired c-axis orientation of the Ru and/or reduce magnetic coupling between the SUL (soft magnetic underlayer) and the storage layer.

### KNOWN TECHNOLOGIES

A mass flow controller (MFC) is a device used to measure and control the flow of gases. A mass flow controller is designed and calibrated to control a specific type of gas at a particular range of flow rates. The MFC can be given a setpoint from 0 to 100% of its full scale range but is typically operated in the 10 to 90% of full scale where the best accuracy is achieved. The device will then control the rate of flow to the given setpoint. All mass flow controllers have at least an inlet port, an outlet port, a mass flow sensor and a proportional control valve. The MFC is usually fitted with a closed loop control system which is given an input signal by the operator (or an external circuit/computer) that it compares to the value from the mass flow sensor and adjusts the proportional valve accordingly to achieve the required flow.

1) MFCs commonly used for controlling gas flows need a considerable amount of time to stabilize gas flows after significant changing their flow set-points. FIG. 1 shows an arrangement known in the art with a gas inlet 1, a MFC 2, a vacuum chamber 3, a vent-line 4 and valves 5 and 6. It has been common practice to use such a set-up, where the gas flow from the MFC 2 is either directed into the vacuum chamber 3 or purged into a so-called vent line 4 (e.g. the forevacuum line of the vacuum system). Thus the MFC 2 can always deliver a constant flow. This set-up will be referred to as “gas purge”.

2) Creating gas pressure peaks by gas expansion from a volume filled with gas at sufficiently high pressure (“gas expansion”) can also be considered general knowledge. A typical set-up is depicted in FIG. 2 using a combination of two switchable valves 8 and 9: the expansion volume 7 is filled with gas from gas inlet 1 (pressure determined by the inlet pressure of the gas) while valve 8 is open and valve 9 is closed. Afterwards valve 8 is closed and the gas volume can be expanded into the vacuum chamber 3 by opening valve 9.

3) It is also a matter of common knowledge to use mechanical parts to narrow the pump cross-section for high pressure sputtering (“throttle valve”).

### PROBLEMS IN THE ART

If substrates have to be treated at high gas pressure while trans-port from one chamber to the other should be performed at significantly lower pressure all known current approaches need significant amount of time to stabilize the pressure (in the range of seconds). For the specific case of the 2-step Ru process this film stack is currently deposited in two consecutive vacuum chambers where the first chamber is operated at low to medium pressure and the second chamber is operated at high pressure. Thus two process stations are occupied and two sets of sputtering targets are needed which both increases process costs.

### BRIEF SUMMARY OF THE INVENTION

One aspect of this invention relates to a general solution for generating short pressure pulses and gas pressure stabilization especially suited for high pressure applications in vacuum processing application. In another aspect of the invention solutions for performing a 2-step process at different pressures (e.g. the 2-step Ru process) in one vacuum chamber with precise and fast gas stabilization is being described in order to enable short cycle times.

In an apparatus for controlling a gas-rise pattern in a vacuum treatment process a gas inlet (1) is operatively connected with a mass-flow-controller MFC (2); said MFC (2) being again operatively connected via a first valve (5) with a vacuum chamber (3) and in parallel via second valve (6) with a vent-line (4). Said connection with the vent-line (4) further comprises means for varying the pump cross section of said vent-line (4). In another embodiment the apparatus for controlling a gas-rise pattern in a vacuum treatment process comprises a gas inlet (13) operatively connected with a vacuum chamber (3) via a valve (11), wherein the connection between gas inlet (13) and valve (11) further comprises a diaphragm (12). Another embodiment for an apparatus for controlling a gas-rise pattern in a vacuum treatment process comprises a gas inlet (14) operatively connected with a vacuum chamber (3) via a valve (18) and a vacuum pump (17) operatively connected with the vacuum chamber (3), wherein the connection between the vacuum chamber (3) and the vacuum pump (17) further comprises a throttle valve (16). Further applications encompass the combination of embodiments described above and shown in the drawings.

### BRIEF DESCRIPTION OF THE DRAWINGS

FIGS. 1 and 2 show arrangements known in the art to generate stable pressures or gas pulses in vacuum treatment processes respectively.

FIG. 3 shows an embodiment of the invention using a needle-valve.

FIG. 4 shows experimental results of an embodiment according FIG. 3.

FIG. 5 shows another inventive embodiment with a diaphragm.

FIGS. 6 and 7 show experimental results of an embodiment according to FIG. 5.

FIG. 8 denotes a pressure pattern of a cyclic 2-step-depositionprocess.

FIG. 9 shows a set-up using a throttle valve between a vacuum chamber and a vacuum pump.

FIG. 10: Basic set-up for a 2-step process using 2 MFCs (2nd gasline with gas purge) together with applying a throttle valve in front of the vacuum pump.

FIG. 11: Basic set-up for a 2-step process using 1 MFC and one gas boost line together with applying a throttle valve in front of the vacuum pump.

FIG. 12: Gas rise pattern for the set-up depicted in FIG. 10.

### DETAILED DESCRIPTION OF THE INVENTION

### 1) Means for Fast Gas Pressure Rising and Stabilization

a) Gas Purge with Variable Pump Cross Section of the Vent Line

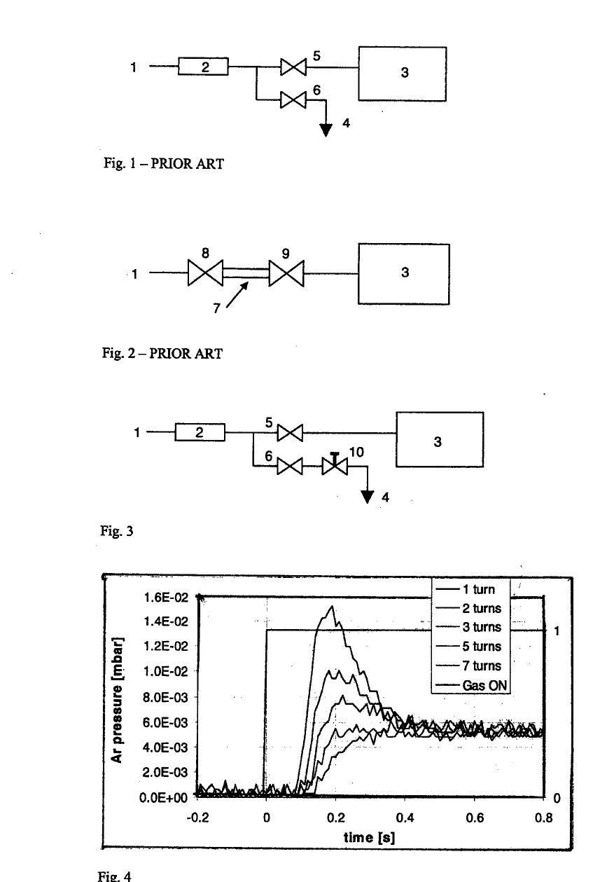

An embodiment of the invention will be described with the aid of FIG. 3. The configuration shows an arrangement emanating from FIG. 1. However, by varying the pump cross section of the vent line 4 (e.g. by means of a needle valve 10) it is possible to control the onset of the gas pressure after switching the gas flow from the vent-line 4 into the vacuum chamber 3 (see FIG. 4)

If the cross section of the vent line 4 is significantly smaller compared to the gas line into the vacuum chamber 3 this leads to a significantly higher pressure in the vent-line and therefore to a gas pressure peak (“gas overshoot”), if the gas flow is switched into the vacuum chamber 3 (i.e. valve 6 into the vent-line is closed and valve 5 into the vacuum chamber is opened at the same time)

On the other hand, if the cross section of the vent line 4 is significantly bigger compared to the gas line into the vacuum chamber 3 the smaller pressure in the vent-line 4 leads to a slow increase of gas pressure (“gas undershoot”).

If appropriate settings for the pump cross section of the vent line are selected the rise of the gas pressure signal can be as short as 0.1 seconds (5 turns of the needle valve in FIG. 4)

FIG. 4 shows experimental results from a set-up of FIG. 3. It is shown the Argon (Ar) gas pressure vs. time for different settings of the needle valve 10. “Turns” means number of turns CCW; zero corresponds to “needle valve completely closed”); “1 turn” corresponds to the uppermost peak, “2 turns” the second one and so forth. “Gas ON” is represented by the step-like graph. As shown, by varying the cross-section of the vent-line 4 via the needle-valve 10 the gas pressure behavior can be prescribed between gas pressure peak (gas overshoot, e.g. “1 turn”) and slow increase of gas pressure (gas undershoot, e.g. “7 turns”).

### b) Gas Boost Using a Combination of a Diaphragm and a Valve

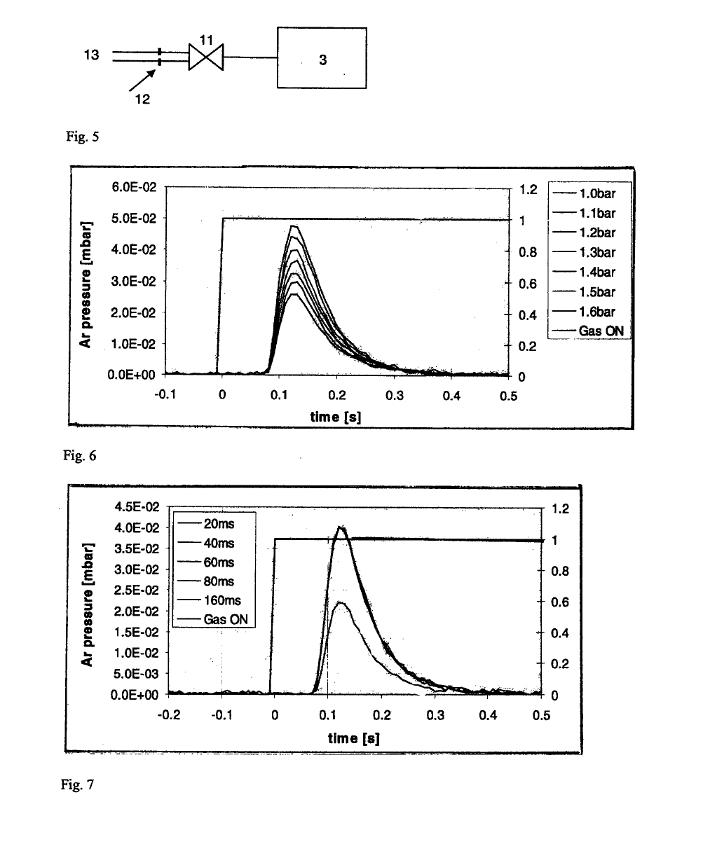

Very short and reproducible gas pressure pulses can also be realized by the set-up depicted in FIG. 5.

A separate gas inlet 13 with variable inlet pressure (e.g. applying a pressure reducing regulator) constantly feeds gas into a volume between a diaphragm 12 (having a very small orifice) and a switchable valve 11. During normal operation of the gas boost set-up for cyclic processing in a vacuum chamber 3 (e.g. processing of substrates in a vacuum apparatus) this gas volume is then expanded into the vacuum chamber by opening of the valve 11.

The aperture of the orifice is chosen such that if the valve 11 was always open the gas flow through the aperture into the vacuum chamber 3 would be negligible (e.g. in the 10⁻⁴ hPa range) compared to the desired process pressure. Thus the gas pressure pattern is virtually independent of the time during which the valve 11 remains open. The only constraint for setting the aperture of the diaphragm 12 is that for the desired cycle time the flow through the aperture has to be high enough to fill the volume in between the aperture of diaphragm 12 and the valve 11.

Using this gas boost set-up a very fast increase in gas pressure can be realized where the height of the pressure peak can be varied by adjusting the gas inlet pressure (see Fig.) or changing the size of the gas expansion volume.

The effect of this gas boost method is similar to the gas expansion method described in Prior Art section 2) but applying only one valve is more cost effective. FIG. 6 shows respective results in gas pressure vs. time in an embodiment according to FIG. 5 for different settings of the inlet pressure from gas inlet 13. “1.0 bar” is represented by the lowest peak, “1.6 bar” by the uppermost peak “Gas ON” is represented by the step-like graph.

FIG. 7 represents gas pressure vs. time for different pulse length of the “valve open” signal showing that after a specific time needed to empty the expansion volume the gas pattern is independent of the opening time of the valve 11. In FIG. 7 “20 ms” represents the lowest peak, graphs for 40-160 ms are represented by the overlay of other graphs. Gas ON=step-like graph.

### 2) 2-Step Processes

One application for the invention is a 2-step process (second step having a significantly different gas pressure compared to first step) by using
a) a fast throttle valve in front of the vacuum pump which is closed/opened in order to increase/decrease the pressure.
b) a throttle valve in combination with adding a second gas (gas purge principle) and/or applying a gas boost for fast pressure increase for the high pressure application.

### a) Throttle Valve Operation

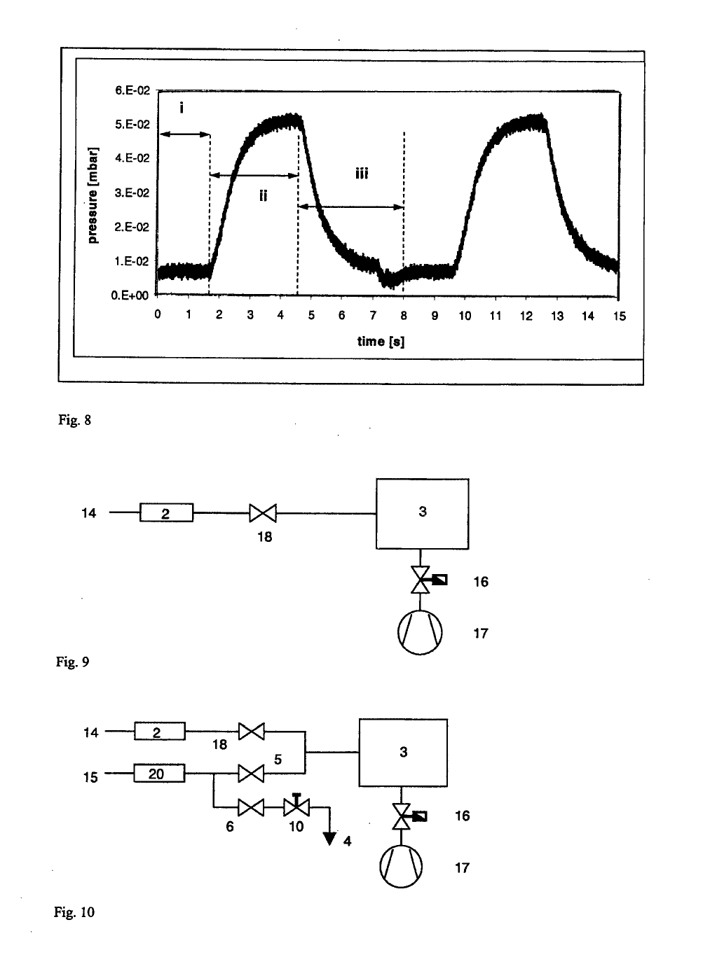

FIG. 8 denotes the pressure pattern of a cyclic 2 step process realized in a setup shown in FIG. 9: A process chamber 3 using one gas inlet 14 with gas purge and a throttle valve 16 between the vacuum chamber 3 and a vacuum pump 17: In FIG. 8 section i shows the gas pressure p1 which is set by the flow set-point of the MFC 2. At the beginning of section ii the throttle valve 16 is closed which leads to a pressure increase, and, after a time of approx. 1.5 s, to a pressure p2 which is governed by the MFC flow together with the specific shape of the throttle valve 16. After section ii the throttle valve 16 is opened again and after a variable time interval (section iii) designated for pump-out the processed substrate is transported into the next chamber whilst a new substrate is brought into the chamber. (Note: In this case the Argon gas flow of the MFC was never turned off since inert gas pressures in the 10⁻³ hPa range are tolerable during transport throughout the system.)

b) Throttle Valve Together with Gas Pulses for Fast Pressure Rise Times

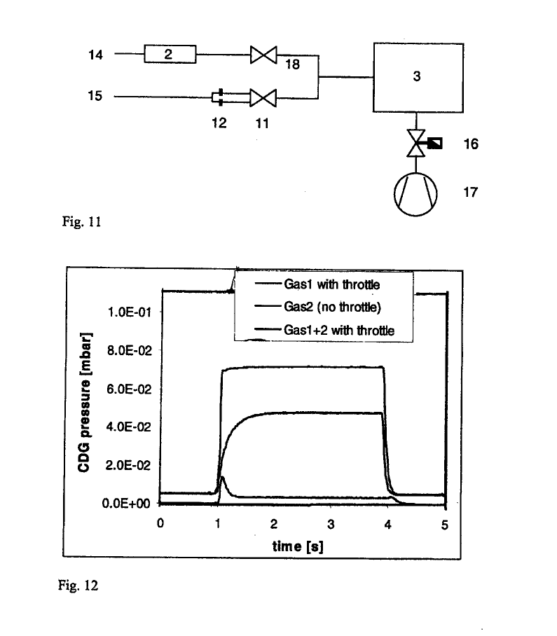

In order to accelerate the pressure rise time at the beginning of section ii (FIG. 8) an additional second MFC 20 and gas purge set-up (as described in paragraph 1a above) or/and the gas boost set-up (as described in paragraph 1b above) are added to the gas manifold. The respective schematics are shown in FIGS. 10 and 11. A respective second gas inlet is marked by reference 15.

In a further embodiment of the invention, e.g. for the gas purge set-up an optimized gas overshoot setting for gas inlet 15 leads to a quasi instantaneous pressure rise. FIG. 12 shows for the set-up of FIG. 10 the gas pressure behaviour for different applications. “Gas 1 with throttle”, the middle graph shows the effect of the branch connected to gas inlet 14. “Gas 2 (no throttle)” is the lowest graph and describes the effect of gas inlet 15 without use of the throttle valve 16. “Gas 1+2 with throttle” describes the effect of using both combined in the uppermost graph.

### FURTHER ADVANTAGES OF THE INVENTION

The gas boost approach is also very well suited as an ignition help for plasma processes (especially RF processes) since it guarantees a very short high pressure pulse which can be set independent of the gas flow used during the process.

1. Apparatus for controlling a gas-rise pattern in a vacuum treatment process comprising:
A gas inlet (1) operatively connected with a mass-flow-controller MFC (2);
Said MFC (2) being again operatively connected via a first valve (5) with a vacuum chamber (3) and in parallel via second valve (6) with a vent-line (4);
Said connection with the vent-line (4) further comprising means for varying the pump cross section of said vent-line (4).

2. Apparatus according to claim 1, wherein the means for varying the pump cross section of the vent-line (4) is a needle-valve (10).

3. Apparatus according to claim 1, wherein the cross section of the vent-line (4) is significantly smaller compared to the gas line into the vacuum chamber (3).

4. Apparatus according to claim 1, wherein the cross section of the vent-line (4) is significantly bigger compared to the gas line into the vacuum chamber (3).

5. Apparatus for controlling a gas-rise pattern in a vacuum treatment process comprising a gas inlet (13) operatively connected with a vacuum chamber (3) via a valve (11), wherein the connection between gas inlet (13) and valve (11) further comprises a diaphragm (12).

5. Apparatus according to claim 5, wherein the gas inlet (13) comprises a pressure reducing regulator for allowing a variable inlet pressure.

6. Apparatus according to claim 5, wherein the connection between diaphragm (12) and valve (11) comprises a volume for gas.

7. Apparatus for controlling a gas-rise pattern in a vacuum treatment process comprising a gas inlet (14) operatively connected with a vacuum chamber (3) via a valve (18) and a vacuum pump (17) operatively connected with the vacuum chamber (3), wherein the connection between the vacuum chamber (3) and the vacuum pump (17) further comprises a throttle valve (16).

8. Apparatus according to claim 7 with a further gas inlet (15) operatively connected with said vacuum chamber (3) via a further mass flow controller (20) and a valve (5), wherein the gas inlet (15) is in parallel connected via said MFC (20) and a further valve (6) with a vent-line (4); said connection with the vent-line (4) further comprising means for varying the pump cross section of said vent-line (4).

9. Apparatus according to claim 7 with a further gas inlet (15) operatively connected with said vacuum chamber (3) via a valve (11), wherein the connection between gas inlet (15) and valve (11) further comprises a diaphragm (12).
